(19) United States
(12) Patent Application Publication
(10) Pub. No.: US 2006/0281338 A1
(43) Pub. Date: Dec. 14, 2006

(54) METHOD FOR PREDICTION OF PREMATURE DIELECTRIC BREAKDOWN IN A SEMICONDUCTOR

(75) Inventors: Kaushik Chanda, Fishkill, NY (US); Hazara S. Rathore, Stormville, NY (US); Paul S. McLaughlin, Poughkeepsie, NY (US); Robert D. Edwards, Marlboro, NY (US); Lawrence A. Clevenger, LaGrangeville, NY (US); Andrew P. Cowley, Wappingers Falls, NY (US); Chih-Chao Yang, Poughkeepsie, NY (US); Conrad A. Barile, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY (US)

(21) Appl. No.: 11/160,213

(22) Filed: Jun. 14, 2005

(51) Int. Cl. H01L 21/00

(52) U.S. Cl. 438/791; 438/5

(57) ABSTRACT

The invention predicts premature dielectric breakdown in a semiconductor. At least one dielectric breakdown mode is calculated for the semiconductor wafer. If a one mode is calculated, premature dielectric breakdown will be associated with any semiconductor with a breakdown voltage less than a predetermined standard deviation of a plurality of breakdown voltages within said calculated mode. If multiple modes are calculated, the mode that most accurately represents dielectric breakdown for the semiconductor wafer is determined and premature dielectric breakdown will be associated with any semiconductor with a breakdown voltage less than a predetermined standard of the calculated mode that most accurately represents dielectric breakdown for the semiconductor wafer.

### FIELD OF THE INVENTION

The invention relates generally to semiconductors and more particularly to predicting premature dielectric breakdown for semiconductors on a semiconductor wafer.

### DESCRIPTION OF THE RELATED ART

Dielectric breakdown is important because dielectric breakdown provides an accurate measure of the Back End of the Line (“BEOL”) reliability of a semiconductor. Semiconductor defects cause dielectric breakdown. Therefore, when one monitors dielectric breakdown, one monitors the health of the manufacturing line.

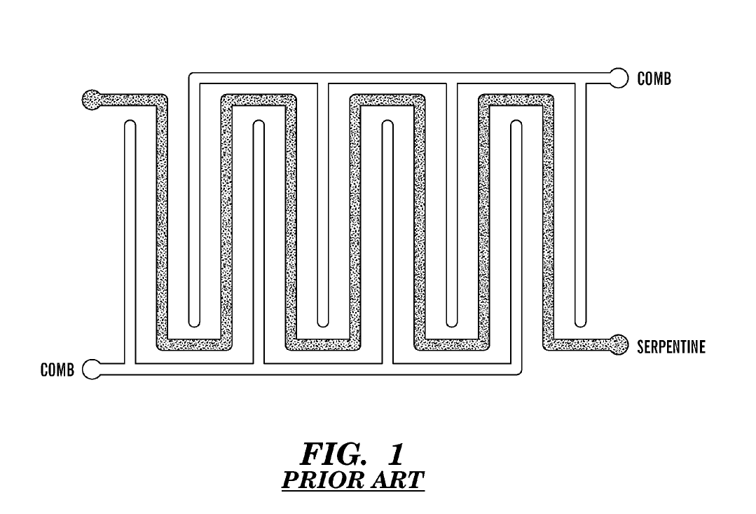

One prior art method for determining dielectric breakdown is time dependent dielectric breakdown (“TDDB”) test, which stresses a semiconductor at a constant voltage, e.g. 12 V, over an extended period of time, e.g. 1000 hours. A serpentine comb structure, such as shown in FIG. 1, is applied to an area 3×10⁶ um² large on the semiconductor and detects any leakage current between a pair of metal lines in the semiconductor. TDDB test is not a wafer level test. Therefore the wafer must be diced and the selected chips must be packaged into modules. Accordingly, TDDB test is expensive because of the associated dicing and packaging costs, e.g. operation of the ovens. In addition, TDDB test is inefficient because the test period extends for over a month. Finally, TDDB test wastes resources because both the wafer and the tested semiconductors are destroyed. For at least these reasons, TDDB test is problematic.

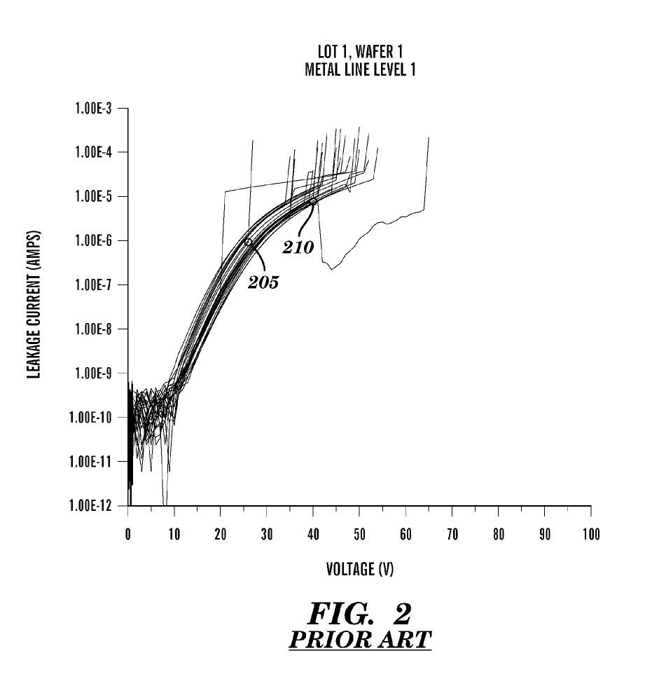

Another prior art method for determining dielectric breakdown is a current voltage (“IV”) test, which stresses a semiconductor at a ramped voltage, e.g. 0-100 V with a step size of 1V, for an abbreviated period of time, e.g. 100 seconds. Similar to TDDB test, a serpentine-comb test structure is used to monitor for leakage current, however unlike TDDB test, IV test is implemented at the wafer level, accordingly the wafer must not be diced and semiconductors must not be packaged. IV test is inefficient because IV test requires the tedious study of IV plots such as shown in FIG. 2 for abrupt increases 205 or decreases 210 in leakage current. Dielectric breakdown occurs whenever the IV plot indicates an abrupt discontinuity in leakage current. Premature dielectric breakdown occurs whenever a chip experiences dielectric breakdown earlier than other chips in the same lot of wafers. Therefore, with continued reference to FIG. 2, the chip that has an abrupt discontinuity in leakage current 205 is unreliable because the chip experiences premature dielectric breakdown at 25 V, while other chips in the same lot of wafers experience dielectric breakdown between 35 and 50 V. IV test is inefficient because it requires the tedious study of IV plots and is therefore impossible to conduct on a large number of chips.

What is needed in the art is an improved method for the determination of dielectric breakdown, which is inexpensive and efficient, can be applied to a large number of chips, and avoids destruction of the semiconductor wafer.

### BRIEF SUMMARY OF THE INVENTION

The invention predicts BEOL reliability efficiently and without destruction of the semiconductor wafer. Therefore, the invention predicts BEOL reliability quickly, while at the same time salvaging the semiconductor wafer. Further, the invention predicts BEOL reliability through the use of pre-existing comb-serpentine structures on the manufacturing line. Accordingly, the invention predicts BEOL reliability without costly modifications to existing manufacturing processes. Finally, the invention is implemented in real time. Accordingly, the invention reduces man hours and avails machines previously reserved for TDDB testing.

For at least the foregoing reasons, the invention improves upon premature dielectric breakdown prediction for semiconductors.

### BRIEF DESCRIPTION OF THE INVENTION

The features and the element characteristics of the invention are set forth with particularity in the appended claims. The figures are for illustrative purposes only and are not drawn to scale. Furthermore, like numbers represent like features in the drawings. The invention itself, however, both as to organization and method of operation, may best be understood by reference to the detailed description which follows, taken in conjunction with the accompanying figures, in which:

FIG. 1 depicts a prior art serpentine comb test structure;

FIG. 2 depicts the results of a prior art IV test;

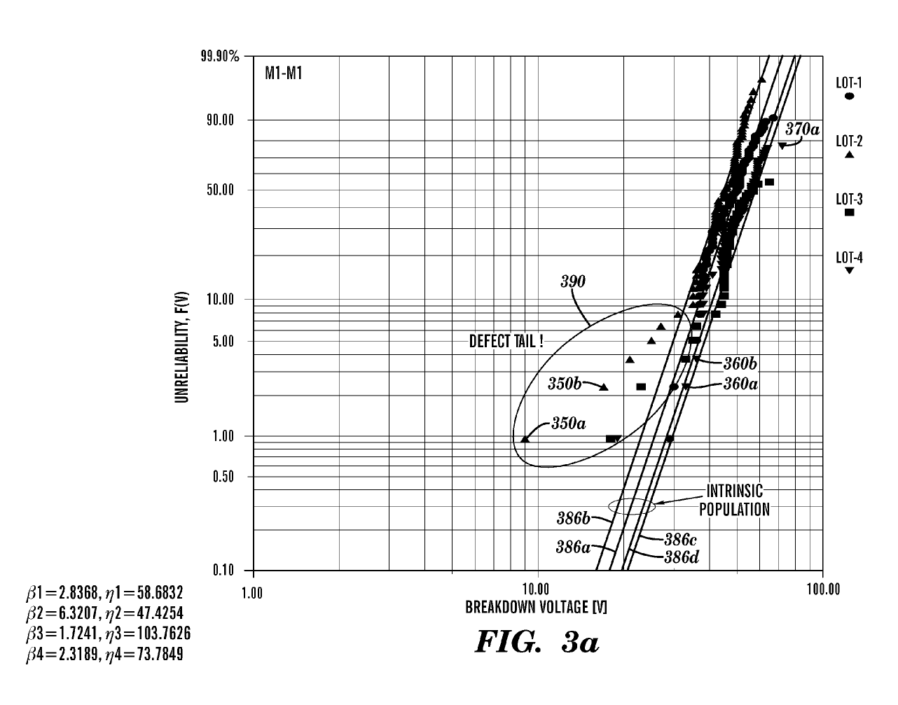

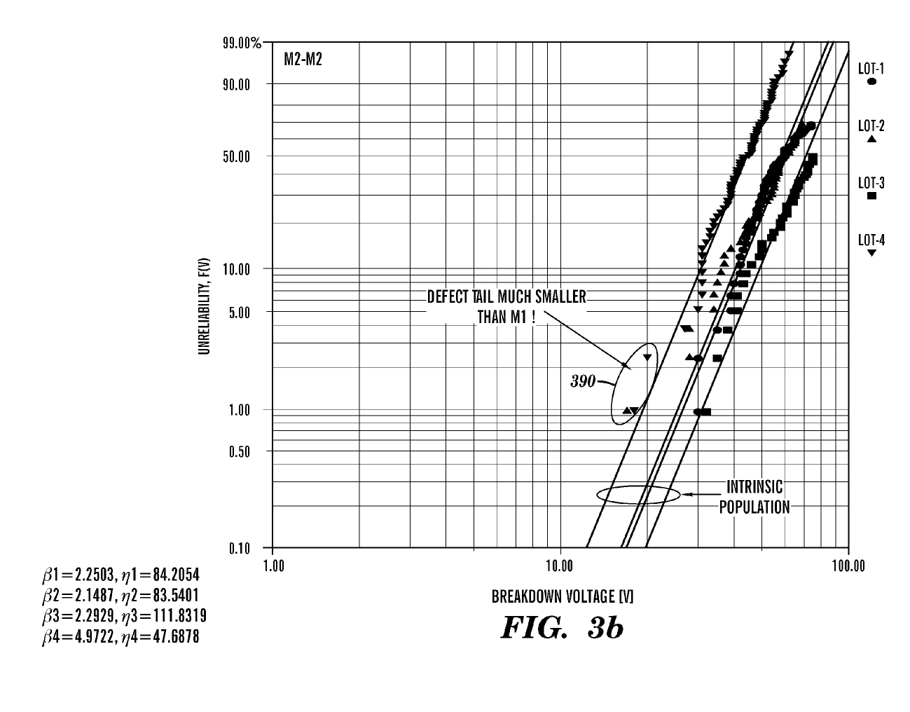

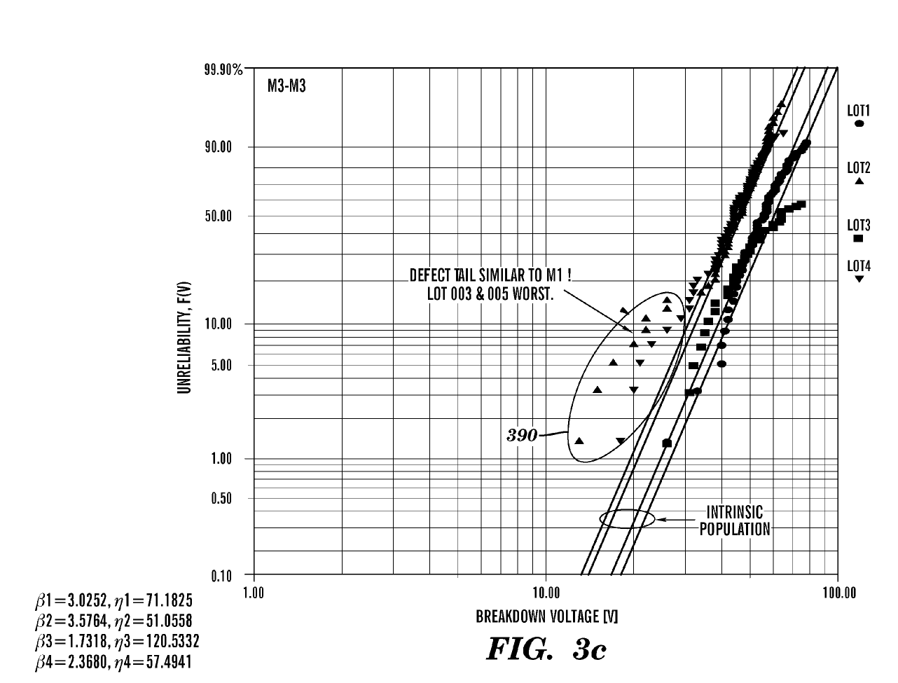

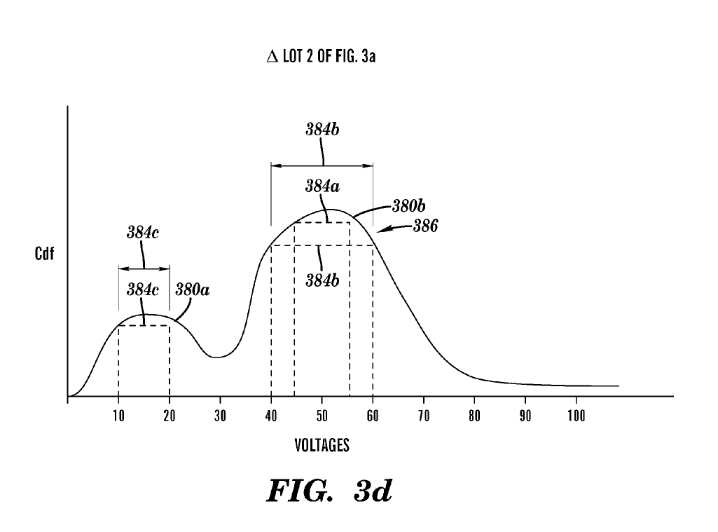

FIGS. 3a-3d depicts calculated modes in a cumulative dielectric breakdown distribution in accordance with a preferred embodiment of the invention;

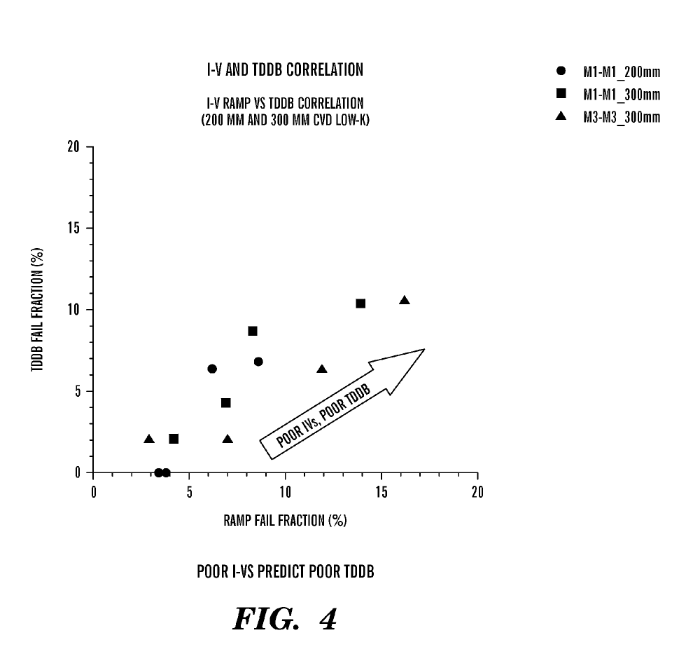

FIG. 4 depicts results of dielectric breakdown prediction determined in accordance with the prior art versus predicted in accordance with the preferred embodiment of the invention;

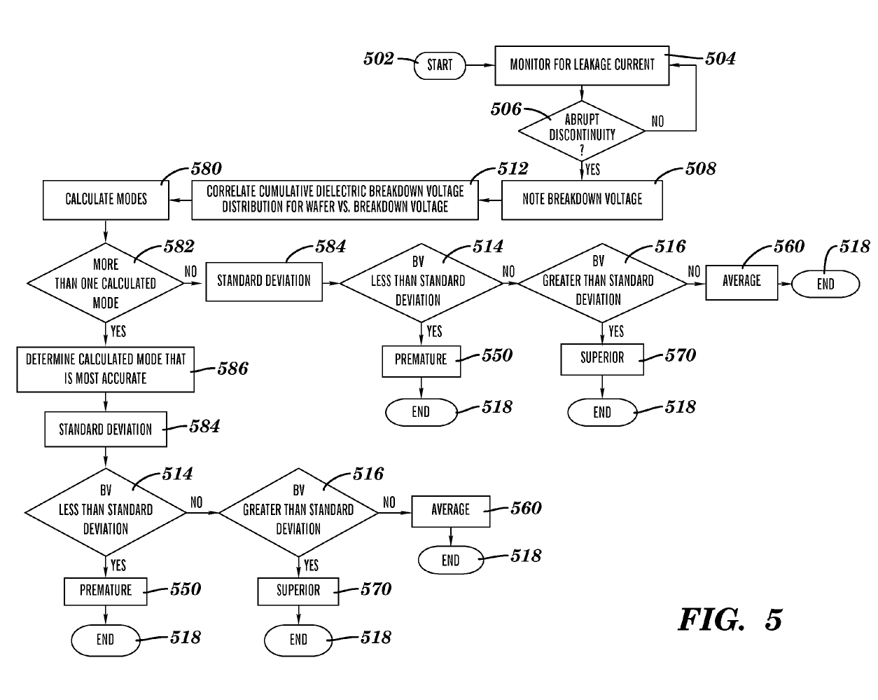

FIG. 5 depicts the method of the preferred embodiment of the invention; and,

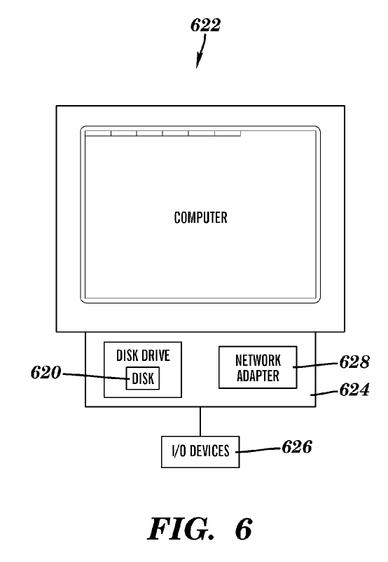

FIG. 6 depicts the program product of the preferred embodiment of the invention.

### DETAILED DESCRIPTION OF THE INVENTION

The invention will now be described with reference to the accompanying figures. In the figures, various aspects of the structures have been shown and schematically represented in a simplified manner to more clearly describe and illustrate the invention.

By way of overview and introduction, the invention comprises an improved method for efficiently predicting dielectric breakdown that occurs in real time with minimal implementation cost and without destruction of the semiconductor wafer. Defects in semiconductors cause premature dielectric breakdown. Accordingly, by predicting premature dielectric breakdown in real time, the invention accomplishes an accurate assessment of the health of the manufacturing line at any given moment in time.

The preferred embodiment of the invention calculates at least one mode dielectric breakdown mode for a semiconductor wafer. The mode comprises a cumulative dielectric breakdown distribution for the wafer versus breakdown voltage for each of a representative population of semiconductors. The cumulative dielectric breakdown distribution indicates the percentage of semiconductors in a representative population of semiconductors with dielectric breakdown by a particular voltage. The cumulative dielectric distribution may indicate, for example, that 80% of the wafer's semiconductors demonstrate dielectric breakdown by 70V, while only 1% demonstrate dielectric breakdown by 11V. Further the cumulative dielectric breakdown distribution may indicate a single calculated mode or two calculated modes, i.e. a unimodal distribution or bimodal distribution of dielectric breakdown for the semiconductor wafer. Based upon the calculated modes in the cumulative distribution, the invention predicts premature dielectric breakdown. More specifically, in response to a single calculated mode, the invention associates premature dielectric breakdown with any semiconductor with a breakdown voltage less than a predetermined standard deviation of a plurality of breakdown voltages within the calculated mode. In response to multiple calculated modes, the invention determines the calculated mode that most accurately represents dielectric breakdown for the semiconductor wafer and associates premature dielectric breakdown with any semiconductor with a breakdown voltage less than the predetermined standard deviation of this calculated mode that most accurately represents dielectric breakdown for the semiconductor wafer.

FIGS. 3a-3c depict calculated modes in accordance with an embodiment of the invention. FIGS. 3a-3c depict the cumulative dielectric breakdown distribution on the y axis and the breakdown voltage on the x axis of a Weibull graph. The solid lines 386a-386d represent the calculated mode that most accurately represents dielectric breakdown for four lots of wafers. The defect tail 390 represents a second calculated mode. Accordingly, lots with a defect tail 390 demonstrate a bimodal dielectric breakdown distribution. Any semiconductor with a data point within a predetermined standard deviation of the calculated mode that most accurately represents dielectric breakdown for the semiconductor wafer is within the intrinsic population. The Weibull statistics of β and η are depicted for four lots of wafers. β represents the slope of the calculated mode, while η represents the breakdown voltage by which 63.2 percent of the population will experience dielectric breakdown for each of the four lots. The steeper the slope, β, the less deviation in breakdown voltages for a given lot. In FIGS. 3a-3c, the dielectric breakdown test results are depicted for a given metal line of semiconductors in four lots of wafers. A representative population of semiconductors, for example twenty four semiconductors, are tested in line and at the wafer level. The representative population of semiconductors is represented by circles, triangles, squares, and inverted triangles for lot 1, lot 2, lot 3, and lot 4, respectively. Dielectric breakdown for each semiconductor of the representative population is plotted against the cumulative dielectric breakdown distribution for the semiconductor wafer. As mentioned herein above, FIGS. 3a-3c depict the calculated mode that most accurately represents dielectric breakdown 386 for four lots of wafers, as well as other calculated modes, such as the defect tail 390. Therefore, semiconductors with a breakdown voltage less than a predetermined standard deviation of the calculated mode that most accurately represents dielectric breakdown are associated with premature dielectric breakdown, while semiconductors with a breakdown voltage within the predetermined standard deviation or greater than the predetermined standard deviation of the calculated mode are associated with average and superior dielectric breakdown, respectively. Semiconductors with a breakdown voltage less than a predetermined standard deviation of the calculated mode that most accurately represents dielectric breakdown for the semiconductor wafer are found in the defect tail 390 of FIGS. 3a-3c.

With continued reference to FIG. 3a, FIG. 3a represents the Weibull graph for metal line 1 of semiconductors for lots one through four. The semiconductor represented by the triangular data point 350a, which is a lot 2 semiconductor, had a cumulative dielectric breakdown distribution of 0.9% and a breakdown voltage of 9V. In other words, only 0.9% of the semiconductors in the lot one wafer experienced dielectric breakdown by 9V. Because dielectric breakdown occurred with a breakdown voltage less than a predetermined standard deviation of the calculated mode that most accurately represents dielectric breakdown for the wafer for lot 2, 386b, premature dielectric breakdown will be associated with the semiconductor represented by data point 350a. For the same reasons, premature dielectric breakdown will be associated with semiconductor represented by data point 350b and all other semiconductors in the defect tail 390. Such semiconductors have weak BEOL reliability.

With reference to inverted triangular data points 360a and 360b in FIG. 3a, which represent semiconductors tested in lot four, the semiconductors tested had a cumulative dielectric breakdown between 2 and 4% and a breakdown voltage between 11-12V. In other words, between 2 and 4% of the semiconductors in the lot four wafer, experienced dielectric breakdown by between 11-12V. Because the dielectric breakdown occurred within a predetermined standard deviation for the calculated mode that most accurately represents dielectric breakdown for the semiconductor wafers in lot 4, 386d, however, premature dielectric breakdown is not associated with the semiconductors represented by data points 360a and 360b. Instead, because the semiconductors represented by data points 360a and 360b occurred within the predetermined standard deviation, average dielectric breakdown is associated with the semiconductors represented by data points 360a and 360b.

With reference to inverted triangular data point 370a in FIG. 3a, which represents a semiconductor tested in lot four, the semiconductor had a cumulative dielectric breakdown between 70 and 80% and a breakdown voltage of 70V. In other words, by 70V between 70 and 80% of the semiconductors in the lot four wafer experienced dielectric breakdown. Because the dielectric breakdown occurred at a breakdown voltage greater than a predetermined standard deviation of the calculated mode that most accurately represents dielectric breakdown for the semiconductor wafer for lot 4, 386d, premature dielectric breakdown is not associated with the semiconductor represented by data point 370a. Instead, superior dielectric breakdown is associated with the semiconductor represented by data point 370.

FIGS. 3b and 3c depict metal lines two and three, respectively, for each of the four lots of wafers. Once again, the semiconductors represented by the data points within the defect tail 390 represent semiconductors associated with premature dielectric breakdown. Therefore, such semiconductors represented by data points within defect tail 390 have weak BEOL reliability. As shown in FIG. 3b, the BEOL reliability improved for metal line two because fewer semiconductors have a breakdown voltage less than the predetermined standard deviation and within the defect tail 390. However, as shown in FIG. 3c, the BEOL reliability worsened for metal line 3 because more semiconductors were represented by data points within the defect tail 390. FIGS. 3a-3c demonstrate that BEOL reliability for a given semiconductor can differ by metal line level.

FIG. 3d depicts the cumulative distribution function (“cdf”) of semiconductors from lot 2 from FIG. 3a. Two calculated modes 380a,b are shown in FIG. 3d, i.e. FIG. 3d depicts a bimodal distribution. Two calculated modes 380 a,b are depicted because a number of semiconductors from lot 2 experienced dielectric breakdown between 10 and 20 volts, but the largest number of semiconductors from lot 2 experienced dielectric breakdown between 40 and 60 volts. Calculated mode 386 best represents dielectric breakdown for the wafer because the largest number of semiconductors from lot 2 experienced dielectric breakdown between 40 and 60 volts. At least one standard deviation 384 was calculated for both calculated modes. For calculated mode 386, two standard deviations, 384a,b were calculated. In so doing, the preferred embodiment associates premature dielectric breakdown with any semiconductor with a breakdown voltage less than a predetermined standard deviation of a plurality of breakdown voltages within said calculated mode. As one of ordinary skill in the art would know, such predetermined standard deviation could be the first standard deviation 384a, the first through second standard deviation 384a,b respectively, or any other predetermined standard deviation that would isolate semiconductors with premature dielectric breakdown from the semiconductors with average and superior dielectric breakdown.

With continued reference to FIG. 3a and FIG. 3d, the lot 2 semiconductors in the defect tail 390 in FIG. 3a represents semiconductors in calculated mode 380a. Most of the lot 2 semiconductors, which are represented by triangles in FIG. 3a, in the defect tail 390 experience dielectric breakdown between 10 and 30 volts. Similarly, the calculated mode 380a depicts that most of the semiconductors in calculated mode 380a experience dielectric breakdown between 10 and 30 volts.

FIG. 4 depicts results of dielectric breakdown prediction determined in accordance with the prior art versus predicted in accordance with the invention. Data points representing semiconductors in the first metal line of a 200 mm wafer, the first metal line in a 300 mm wafer, and the third metal line in a 300 mm wafer are represented in FIG. 4. The y axis represents the prior art test results while the x axis represents the invention's test results. As shown, the prior art test results are directly proportional to the invention's test results. Accordingly, the invention predicts dielectric breakdown at least as accurately as the prior art.

FIG. 5 depicts the method of the preferred embodiment. In step 504, the invention monitors for leakage current. In step 506, abrupt discontinuities in leakage current are noted. In step 508, breakdown voltage is noted for the semiconductor at the abrupt discontinuity. Notation of breakdown voltage is in accordance with the preferred embodiment of the invention, but is just one indication of dielectric breakdown. Instead of breakdown voltage, a breakdown current could be noted in step 508 in accordance with an alternative embodiment of the invention. Once breakdown voltage is noted in step 508, in step 512 cumulative dielectric breakdown distribution for the wafer is correlated with breakdown voltage for the semiconductor. In step 580, the modes of for the wafer is calculated. In step 582, it is determined if more than one calculated mode exists. If so, the calculated mode that most accurately represents the wafer is determined in step 586. Otherwise, a predetermined standard deviation is determined for the single calculated mode in step 584.

In FIG. 5, once a predetermined standard deviation for the single calculated mode is determined in step 584, the breakdown voltage for the semiconductors in the representative population is compared. If the breakdown voltage is less than the standard deviation in step 514, premature dielectric breakdown is associated with that semiconductor in step 550. Otherwise, the preferred embodiment queries if the breakdown voltage is greater than the standard deviation in step 516. If so, superior dielectric breakdown is associated with the semiconductor in step 570. Otherwise, the preferred embodiment associates average dielectric breakdown with the semiconductor in step 560.

In FIG. 5, once the calculated mode that most accurately represents dielectric breakdown for the wafer has been determined in step 586, a predetermined standard deviation is determined in step 586. If the breakdown voltage is less than the standard deviation in step 514, premature dielectric breakdown is associated with that semiconductor in step 550. Otherwise, the preferred embodiment queries if the breakdown voltage is greater than the standard deviation in step 516. If so, superior dielectric breakdown is associated with the semiconductor in step 570. Otherwise, the preferred embodiment associates average dielectric breakdown with the semiconductor in step 560.

FIG. 6 depicts the program product of the preferred embodiment of the invention. The invention can take the form of an entirely hardware embodiment, an entirely software embodiment or an embodiment containing both hardware and software elements. In a preferred embodiment, the invention is implemented in software, which includes but is not limited to firmware, resident software, and microcode. Furthermore, the invention can take the form of a computer program product 620 accessible from a computer-usable or computer-readable medium providing program code for use by or in connection with a computer 622 or any instruction execution system. For the purposes of this description, a computer-usable or computer readable medium can be any apparatus that can contain, store, communicate, propagate, or transport the program for use by or in connection with the instruction execution system, apparatus, or device. The medium 620 can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD. A data processing system 624 suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution. Input/output or I/O devices 626 (including but not limited to keyboards, displays, and pointing devices) can be coupled to the system either directly or through intervening I/O controllers. Network adapters 628 may also be coupled to the system to enable the data processing system to become coupled to other data processing systems or remote printers or storage devices through intervening private or public networks. Modems, cable modem and Ethernet cards are just a few of the currently available types of network adapters.

In sum, the invention predicts BEOL reliability efficiently, accurately, and without destruction of the semiconductor wafer. In addition, the invention simplifies BEOL reliability testing, such that BEOL reliability in accordance with the invention can be implemented on a large number of semiconductors. Finally, because the invention monitors for premature dielectric breakdown, an indication of a semiconductor defects, in real time, the invention enables an accurate assessment on the health of the manufacturing line at any given moment in time.

While the invention has been particularly described in conjunction with a specific preferred embodiment and other alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the invention.

What is claimed is:

1. A method for predicting premature dielectric breakdown in a semiconductor, comprising, the steps of:
calculating at least one dielectric breakdown mode for a semiconductor wafer;
in response to a single calculated mode, associating premature dielectric breakdown with any semiconductor with a breakdown voltage less than a predetermined standard deviation of a plurality of breakdown voltages within said calculated mode; and,
in response to a plurality of calculated modes, determining a calculated mode of said calculated modes that most accurately represents dielectric breakdown for said semiconductor wafer and associating premature dielectric breakdown with any semiconductor with a breakdown voltage less than a predetermined standard deviation of a plurality of breakdown voltages within said calculated mode that most accurately represents dielectric breakdown for said semiconductor wafer.

2. A method as in claim 1, wherein said mode comprises a cumulative dielectric breakdown distribution for said wafer versus breakdown voltage for each of a representative population of semiconductors on said wafer.

3. A method as in claim 2 further comprising, the step of:
correlating said cumulative dielectric breakdown distribution for said wafer with breakdown voltage for each semiconductor in said representative population.

4. A method as in claim 3 further comprising, the step of:
receiving a breakdown voltage for each semiconductor in said representative population.

5. A method as in claim 3 further comprising, the step of:
determining breakdown voltage for each semiconductor in said representative population, which comprises the steps of:
applying a plurality of increasing voltages to each semiconductor in said population; and,
monitoring leakage current between metal lines in said semiconductor for any abrupt discontinuity in leakage current;
wherein breakdown voltage is said voltage of said semiconductor at said abrupt discontinuity.

6. A method as in claim 2, wherein said cumulative dielectric breakdown distribution represents a percentage of semiconductors in said representative population with dielectric breakdown by a particular breakdown voltage.

7. A method as in claim 5, wherein said abrupt discontinuity comprises one of an abrupt increase and decrease in leakage current.

8. A method as in claim 1 further comprising, the step of:
in response to a single calculated mode, associating average dielectric breakdown with any semiconductor with a breakdown voltage within said predetermined standard deviation of a plurality of breakdown voltages within said calculated mode; and,
in response to a plurality of calculated modes, associating average dielectric breakdown with any semiconductor with a breakdown voltage within said predetermined standard deviation of breakdown voltages of said calculated mode that most accurately represents dielectric breakdown for said semiconductor wafer.

9. A method as in claim 8 further comprising, the step of:
in response to a single calculated mode, associating superior dielectric breakdown with any semiconductor with a breakdown voltage greater than a predetermined standard deviation of a plurality of breakdown voltages of said calculated mode; and,
in response to a plurality of calculated modes, associating superior dielectric breakdown with any semiconductor with a breakdown voltage greater than a predetermined standard deviation of a plurality of breakdown voltages within said calculated mode that most accurately represents dielectric breakdown for said semiconductor wafer.

10. A method for predicting premature dielectric breakdown in a semiconductor, comprising, the steps of:
calculating at least one dielectric breakdown mode for a semiconductor wafer;
in response to a single calculated mode, associating premature dielectric breakdown with any semiconductor with an indication of dielectric breakdown less than a predetermined standard deviation of a plurality of breakdown voltages within said calculated mode; and,
in response to a plurality of calculated modes, determining the calculated mode of said calculated modes that most accurately represents dielectric breakdown for said semiconductor wafer and associating premature dielectric breakdown with any semiconductor with an indication of dielectric breakdown less than a predetermined standard deviation of a plurality of breakdown voltages within said calculated mode that most accurately represents dielectric breakdown for said semiconductor wafer.

11. A method as in claim 10, wherein said mode comprises a cumulative dielectric breakdown distribution for said wafer versus said indication of dielectric breakdown for each semiconductor in a representative population of semiconductors on said wafer.

12. A method as in claim 11, further comprising, the step of:
correlating said cumulative dielectric breakdown distribution for said wafer with one of breakdown current and voltage for each semiconductor in said representative population.

13. A method as in claim 12 further comprising, the step of:
receiving said one of breakdown current and voltage for each semiconductor in said representative population.

14. A method as in claim 12 further comprising, the step of:
determining breakdown current for each semiconductor in said representative population of semiconductors, which comprises the steps of:
applying a plurality of increasing currents to each semiconductor in said plurality; and,
monitoring voltage for any abrupt discontinuity;
wherein breakdown current is said current of said semiconductor at said abrupt discontinuity.

15. A method as in claim 11, wherein said cumulative dielectric breakdown distribution represents a percentage of said semiconductors in said representative population with dielectric breakdown by a particular indication of dielectric breakdown.

16. A method as in claim 13, wherein said abrupt discontinuity comprises one of an abrupt increase and decrease of said one of breakdown current and voltage.

17. A method as in claim 10 further comprising, the step of:
in response to a single calculated mode, associating average dielectric breakdown with any semiconductor with an indication of dielectric breakdown within said predetermined standard deviation of a plurality of indications of dielectric breakdown within said calculated mode; and,
in response to a plurality of calculated modes, associating average dielectric breakdown with any semiconductor with an indication of dielectric breakdown within said predetermined standard deviation of a plurality of indications of dielectric breakdown within said calculated mode that most accurately represents dielectric breakdown for said semiconductor wafer.

18. A method as in claim 17 further comprising, the step of:
in response to a single calculated mode, associating superior dielectric breakdown with any semiconductor with an indication of dielectric breakdown greater than said predetermined standard deviation of a plurality of indications of dielectric breakdown within said calculated mode; and,
in response to a plurality of calculated modes, associating superior dielectric breakdown with any semiconductor with an indication of dielectric breakdown greater than said predetermined standard deviation of said calculated mode that most accurately represents dielectric breakdown for said semiconductor wafer.

19. A method for predicting premature dielectric breakdown in a semiconductor, comprising, the steps of:
monitoring leakage current between a metal line pair in each semiconductor in a representative population of semiconductors on a semiconductor wafer;
associating any abrupt discontinuity of leakage current with dielectric breakdown for said semiconductors in said representative population;
correlating a cumulative dielectric breakdown distribution for said semiconductor wafer with a voltage of said semiconductors in said representative population at said abrupt discontinuity;
calculating at least one mode in a cumulative dielectric breakdown distribution for said semiconductor wafer; and,
in response to a single calculated mode, associating premature dielectric breakdown with any semiconductor with a breakdown voltage less than a predetermined standard deviation of a plurality of breakdown voltages within said calculated mode; and,
in response to a plurality of calculated modes, determining the calculated mode of said calculated modes that most accurately represents dielectric breakdown for said semiconductor wafer and associating premature dielectric breakdown with any semiconductor with a breakdown voltage less than a predetermined standard deviation of a plurality of breakdown voltages within said calculated mode that most accurately represents dielectric breakdown for said semiconductor wafer.

20. A method as in claim 19, wherein said mode comprises a cumulative dielectric breakdown distribution for said wafer versus said voltage of each semiconductor in said representative population of semiconductors at said abrupt discontinuity.

21. A method as in claim 20, wherein said cumulative dielectric breakdown distribution represents a percentage of said semiconductors in said representative population with dielectric breakdown by a particular breakdown voltage.

22. A method as in claim 19, wherein said abrupt discontinuity comprises one of an abrupt increase and decrease of leakage current.

23. A method as in claim 19 further comprising, the step of:
in response to a single calculated mode, associating average dielectric breakdown with any semiconductor with a breakdown voltage within said predetermined standard deviation of a plurality of breakdown voltages within said calculated mode; and,
in response to a plurality of calculated modes, associating average dielectric breakdown with any semiconductor with a breakdown voltage within said predetermined standard deviation of a plurality of breakdown voltages within said calculated mode that most accurately represents dielectric breakdown for said semiconductor wafer.

24. A method as in claim 23 further comprising, the step of:
in response to a single calculated mode, associating superior dielectric breakdown with any semiconductor with a breakdown voltage greater than said predetermined standard deviation of a plurality of breakdown voltages within said calculated mode; and,
in response to a plurality of calculated modes, associating superior dielectric breakdown with any semiconductor with a breakdown voltage greater than said predetermined standard deviation of a plurality of breakdown voltages within said calculated mode that most accurately represents dielectric breakdown for said semiconductor wafer.

25. A computer program product comprising a computer useable medium including a computer readable program, wherein the computer readable program when executed on a computer causes the computer to:
calculating at least one dielectric breakdown mode for a semiconductor wafer;
in response to a single calculated mode, associating premature dielectric breakdown with any semiconductor with a breakdown voltage less than a predetermined standard deviation of a plurality of breakdown voltages within said calculated mode; and,
in response to a plurality of calculated modes, determining a calculated mode of said calculated modes that most accurately represents dielectric breakdown for said semiconductor wafer and associating premature dielectric breakdown with any semiconductor with a breakdown voltage less than a predetermined standard deviation of a plurality of breakdown voltages within said calculated mode that most accurately represents dielectric breakdown for said semiconductor wafer.

26. A computer program product comprising a computer useable medium including a computer readable program, wherein the computer readable program when executed on a computer causes the computer to:
calculating at least one dielectric breakdown mode for a semiconductor wafer;
in response to a single calculated mode, associating premature dielectric breakdown with any semiconductor with an indication of dielectric breakdown less than a predetermined standard deviation of a plurality of breakdown voltages within said calculated mode; and,
in response to a plurality of calculated modes, determining the calculated mode of said calculated modes that most accurately represents dielectric breakdown for said semiconductor wafer and associating premature dielectric breakdown with any semiconductor with an indication of dielectric breakdown less than a predetermined standard deviation of a plurality of breakdown voltages within said calculated mode that most accurately represents dielectric breakdown for said semiconductor wafer.

27. A computer program product comprising a computer useable medium including a computer readable program, wherein the computer readable program when executed on a computer causes the computer to:
monitoring leakage current between a metal line pair in each semiconductor in a representative population of semiconductors on a semiconductor wafer;
associating any abrupt discontinuity of leakage current with dielectric breakdown for said semiconductors in said representative population;
correlating a cumulative dielectric breakdown distribution for said semiconductor wafer with a voltage of said semiconductors in said representative population at said abrupt discontinuity;
calculating at least one mode in a cumulative dielectric breakdown distribution for said semiconductor wafer; and,
in response to a single calculated mode, associating premature dielectric breakdown with any semiconductor with a breakdown voltage less than a predetermined standard deviation of a plurality of breakdown voltages within said calculated mode; and,
in response to a plurality of calculated modes, determining the calculated mode of said calculated modes that most accurately represents dielectric breakdown for said semiconductor wafer and associating premature dielectric breakdown with any semiconductor with a breakdown voltage less than a predetermined standard deviation of a plurality of breakdown voltages within said calculated mode that most accurately represents dielectric breakdown for said semiconductor wafer.
